(19) United States
(12) Patent Application Publication
(10) Pub. No.: US 2026/0271208 A1
(43) Pub. Date: Sep. 10, 2026

(54) TILED ELECTRONIC DEVICE AND MANUFACTURING METHOD THEREOF

(71) Applicant: InnoLux Corporation, Miao-Li County (TW)

(72) Inventor: Hung-Ming HSIEH, Miao-Li County (TW)

(21) Appl. No.: 19/536,801

(22) Filed: Feb. 11, 2026

(30) Foreign Application Priority Data
Mar. 7, 2025 (CN) 202510266942.2

(51) Int. Cl. H05K 5/30

(52) U.S. Cl. CPC H05K 5/30

(57) ABSTRACT

A tiled electronic device includes: a frame and a tiled electronic module. The tiled electronic module includes: a bracket assembly including a plurality of brackets fixed to one another, the bracket assembly being provided with a first side and a second side opposite to each other; a plurality of electronic modules disposed on the first side of the bracket assembly; and a plurality of positioning blocks disposed on the bracket assembly, each of the plurality of positioning blocks having a support surface disposed on the second side, wherein the tiled electronic module is placed against the frame through the support surfaces.

### CROSS-REFERENCE TO RELATED APPLICATIONS

This application claims the benefit of the Chinese Patent Application Serial Number 202510266942.2, filed on Mar. 7, 2025, the subject matters of which are incorporated herein by reference.

### BACKGROUND

### Field of the Disclosure

The present disclosure provides an electronic device and a manufacturing method thereof and, more particularly, to a tiled electronic device and a manufacturing method thereof.

### Description of Related Art

In recent years, with the development of science and technology and the gradual increase in market demand, various tiled electronic devices have emerged. However, in order to achieve a consistent display effect after tiling and alleviate the poor visual effect caused by tiling, the accuracy of each component in the tiled electronic device is extremely high. The existing solution is to increase the precision of the parts, reduce the tolerance, or reduce the assembly error. However, for production, a certain tolerance margin is necessary, which is related to the yield rate and production cost. In addition, the production and assembly involves a plurality of assembly and surface treatment processes, which will more or less produce some dimensional variation. The allowable value of these variations also has a profound impact on the manufacturability of the product. Therefore, the existing method only can strike a balance between effect and cost, otherwise it may increase production costs unnecessarily.

Therefore, there is an urgent need to provide an improved tiled electronic device and a manufacturing method thereof so as to alleviate and/or obviate the aforementioned defects.

### SUMMARY

The present disclosure provides a tiled electronic device, which includes: a frame; and a tiled electronic module, including: a bracket assembly including a plurality of brackets fixed to one another, the bracket assembly being provided with a first side and a second side opposite to each other; a plurality of electronic modules disposed on the first side of the bracket assembly; and a plurality of positioning blocks disposed on the bracket assembly, each of the plurality of positioning blocks having a support surface disposed on the second side; wherein the tiled electronic module is placed against the frame through the support surfaces.

The present disclosure further provides a method for manufacturing a tiled electronic device, which includes the steps of: providing a first platform; placing a plurality of electronic modules in parallel on the first platform; fixing a plurality of brackets on the plurality of electronic modules, respectively; fixing the plurality of brackets to form a bracket assembly; providing a second platform and arranging a plurality of positioning blocks on one side of the second platform; enabling the first platform and the side of the second platform to be separated by a predetermined distance; fixing the plurality of positioning blocks on the bracket assembly; and placing the plurality of positioning blocks against a frame.

Other novel features of the disclosure will become more apparent from the following detailed description when taken in conjunction with the accompanying drawings.

### BRIEF DESCRIPTION OF DRAWINGS

FIG. 1 is a schematic diagram of a tiled electronic device according to an embodiment of the present disclosure;

FIG. 2 is an exploded view of a tiled electronic device according to an embodiment of the present disclosure; and

FIG. 3 to FIG. 12 are schematic diagrams illustrating a method for manufacturing a tiled electronic device according to an embodiment of the present disclosure.

### DETAILED DESCRIPTION OF EMBODIMENT

The electronic device according to the embodiment of the present disclosure is described in detail below. It should be understood that the following description provides many different embodiments for implementing different aspects of some embodiments of the present disclosure. The specific components and arrangements described below are only for the purpose of simply and clearly describing some embodiments of the present disclosure. Of course, these are only examples and are not limitations of the present disclosure. In addition, similar and/or corresponding reference numerals may be used in different embodiments to identify similar and/or corresponding components in order to clearly describe the present disclosure. However, the use of these similar and/or corresponding reference numerals is only for simply and clearly describing some embodiments of the present disclosure, and does not represent any relationship between the different embodiments and/or structures discussed.

The embodiments of the present disclosure may be understood together with the drawings, and the drawings of the present disclosure are also regarded as part of the disclosure description. It should be understood that the drawings of the present disclosure are not in scale and, in fact, the dimensions of elements may be arbitrarily enlarged or reduced in order to clearly illustrate features of the present disclosure. In addition, directional terms mentioned in the specification, such as “up”, “down”, “front”, “rear”, “left”, “right”, etc., only refer to the directions of the drawings. Accordingly, the directional term used is illustrative, not limiting, of the present disclosure. In the drawings, various figures illustrate the general characteristics of methods, structures and/or materials used in particular embodiments. However, these drawings should not be construed to define or limit the scope or nature encompassed by these embodiments. For example, the relative sizes, thicknesses and positions of various layers, regions and/or structures may be reduced or enlarged for clarity.

One structure (or layer, component, substrate) described in the present disclosure is disposed on/above another structure (or layer, component, substrate), which can mean that the two structures are adjacent and directly connected, or can refer to two structures that are adjacent rather than directly connected. Indirect connection means that there is at least one intermediate structure (or intermediate layer, intermediate component, intermediate substrate, intermediate space) between the two structures, the lower surface of one structure is adjacent to or directly connected to the upper surface of the intermediate structure, and the upper surface of the other structure is adjacent to or directly connected to the lower surface of the intermediate structure. The intermediate structure may be a single-layer or multi-layer physical structure or a non-physical structure, which is not limited. In the present disclosure, when a certain structure is arranged “on” other structures, it may mean that a certain structure is “directly” on other structures, or it means that a certain structure is “indirectly” on other structures; that is, at least one structure is sandwiched, in between a certain structure and other structures.

In addition, it should be understood that, in the specification and claims, unless otherwise specified, ordinal numbers, such as “first” and “second”, used herein are intended to distinguish elements rather than disclose explicitly or implicitly that names of the elements bear the wording of the ordinal numbers. The ordinal numbers do not imply what order an element and another element are in terms of space, time or steps of a manufacturing method. Thus, what is referred to as a “first element” in the specification may be referred to as a “second element” in the claims.

In some embodiments of the present disclosure, terms such as “connection” and “interconnection” about joining and connecting, unless otherwise specified, may mean that two structures are in direct contact, or may also mean that two structures are not in direct contact, where other structures are placed between the two structures. Moreover, the terms about joining and connecting may also include the situation that both structures are movable, or both structures are fixed. In addition, the term “couple” includes any direct and indirect means of electrical connection.

In the description, the terms “almost”, “about”, “approximately” or “substantially” usually means within 10%, 5%, 3%, 2%, 1% or 0.5% of a given value or range. Unless otherwise specified, the term “range between the first value and the second value” indicates that the range includes the first value, the second value, and other values in between. In addition, any two values or directions used for comparison may have certain errors. If the first value is equal to the second value, it implies that there may be an error of about 10% between the first value and the second value. If the first direction is perpendicular to the second direction, it implies that the angle between the first direction and the second direction may be between 80 degrees and 100 degrees. If the first direction is parallel to the second direction, it implies that the angle between the first direction and the second direction may be between 0 degrees and 10 degrees. In the present disclosure, the term “a given range is from a first value to a second value” or “a given range is within a range from the first value to the second value” means that the given range includes the first value, the second value and other values between the first and second values.

Furthermore, according to the embodiments of the present disclosure, an optical microscope (OM), a scanning electron microscope (SEM), an thin film thickness profiler (α-step), an ellipsometer, or other suitable methods may be used to measure the thickness, length, width of each component or the distance and angle between components. In detail, according to some embodiments, a scanning electron microscope may be used to obtain a cross-sectional image of a structure and measure the thickness, length, width of each component or the distance and angle between components.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to”. Therefore, when the terms “comprising”, “including” and/or “having” are used in the description of the present disclosure, they specify the existence of corresponding features, regions, steps, operations and/or components, but do not exclude the existence of one or more corresponding features, regions, steps, operations and/or components.

It should be understood that, without departing from the spirit of the present disclosure, in the following embodiments, the features in different embodiments may be replaced, reorganized or mixed to accomplish other embodiments. The features among various embodiments may be mixed and matched arbitrarily as long as they do not violate the spirit of the invention or conflict with each other.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure. The present disclosure may be understood by referring to the following detailed description in conjunction with the accompanying drawings. It should be noted that, in order to facilitate the understanding of the readers and for the simplicity of the drawings, the multiple drawings in the present disclosure only depict a portion of the electronic device, and the specific components in the drawings are not drawn according to the actual scale. In addition, the number and size of each component in the figure are only for illustration and are not intended to limit the scope of the present disclosure.

The electronic device of the present disclosure may include electronic components. The electronic components may include passive components, active components, or a combination thereof, such as capacitors, resistors, inductors, varactors, variable capacitors, filters, diodes, transistors, sensors, microelectromechanical systems (MEMS), liquid crystal chips, etc., but not limited thereto. The diode may include a light-emitting diode or a non-light-emitting diode. The diode includes a P-N junction diode, a PIN diode, or a constant current diode. The light-emitting diode may include, for example, an organic light-emitting diode (OLED), a sub-millimeter light-emitting diode (mini LED), a micro LED, a quantum dot LED, fluorescence, phosphor, or other suitable materials, or a combination thereof, but not limited thereto. The sensor may include, for example, a capacitive sensor, an optical sensor, an electromagnetic sensor, a fingerprint sensor (FPS), a touch sensor, an antenna, or a stylus sensor, but not limited thereto. In the following description, a display device will be used as an electronic device to illustrate the present disclosure, but the present disclosure is not limited thereto.

The electronic device may include an imaging device, a bonding device, a display device, a backlight device, an antenna device, a tiled device, a touch display, a curved display, or a free shape display, but not limited thereto. The electronic device may, for example, include liquid crystal, a light emitting diode, fluorescence, phosphor, other suitable display media, or a combination thereof, but not limited thereto. The display device may be a non-self-luminous display device or a self-luminous display device. The antenna device may be a liquid crystal antenna device or a non-liquid crystal antenna device, and the sensing device may be a sensing device for sensing capacitance, light, heat, or ultrasound, but not limited thereto. The tiled device may be, for example, a display tiled device or an antenna tiled device, but not limited thereto. It should be noted that the electronic device may be any combination of the foregoing, but not limited thereto. The electronic device may be a bendable or flexible electronic device. It should be noted that the electronic device may be any of the aforementioned arrangements and combinations, but not limited thereto. In addition, the appearance of the electronic device may be rectangular, circular, polygonal, a shape with curved edges, or other suitable shapes. The electronic device may have a peripheral system such as a drive system, a control system, a light source system, a shelf system, etc. to support the display device, antenna device or tiled device. It is noted that the following are exemplary embodiments of the present disclosure, but the present disclosure is not limited thereto, while a feature of some embodiments can be applied to other embodiments through suitable modification, substitution, combination, or separation. In addition, the present disclosure can be combined with other known structures to form further embodiments. It should be noted that the technical solutions provided by the different embodiments described hereinafter may be used interchangeably, combined or mixed to form another embodiment without violating the spirit of the present disclosure.

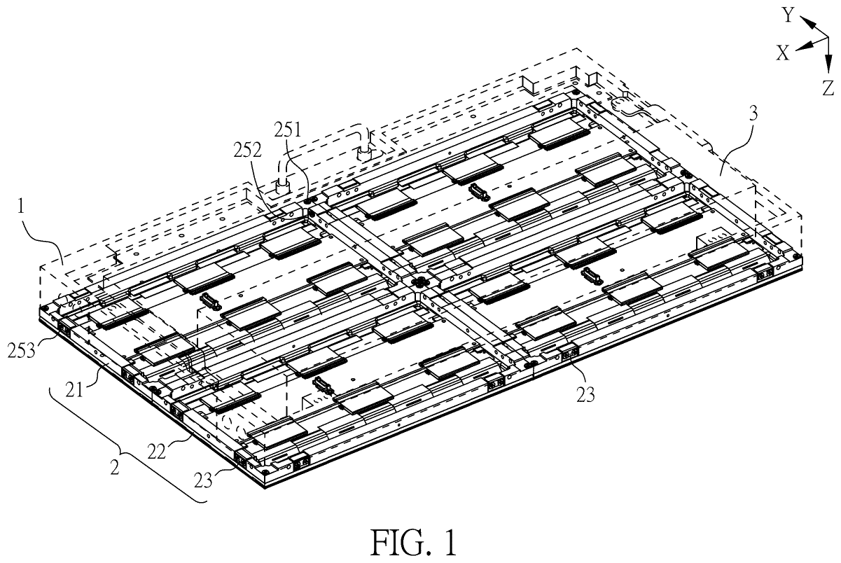

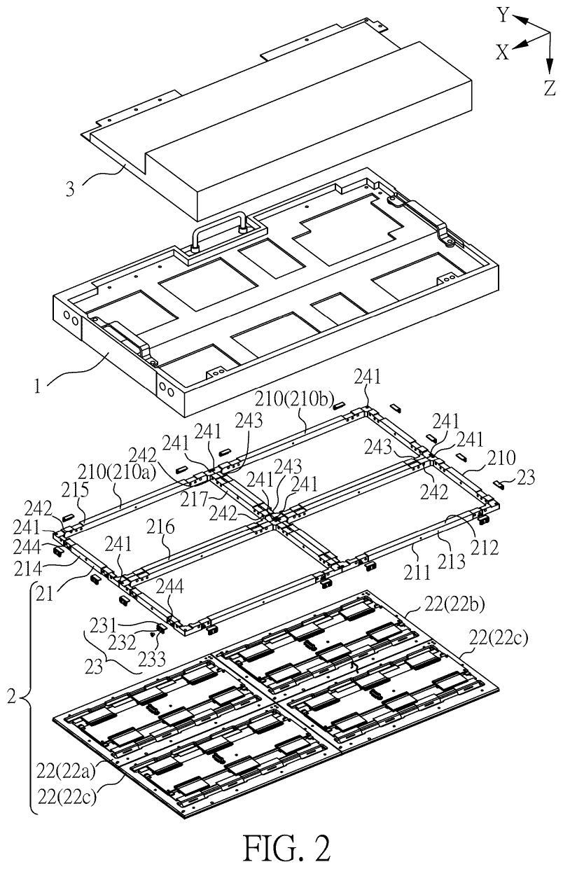

FIG. 1 is a schematic diagram of a tiled electronic device according to an embodiment of the present disclosure, and FIG. 2 is an exploded view of a tiled electronic device according to an embodiment of the present disclosure, wherein, in order to clearly illustrate the first fastening hole 241, the second fastening hole 242, the third fastening hole 243, and the fourth fastening hole 244 of FIG. 2, the first fastening member 251, the second fastening member 252, and the third fastening member 253 of FIG. 1 are not shown in FIG. 2.

As shown in FIG. 1 and FIG. 2, the tiled electronic device includes a frame 1 and a spliced electronic module 2. The tiled electronic module 2 is placed against the frame 1 via a support surface 231. The tiled electronic module 2 includes a bracket assembly 21, a plurality of electronic modules 22, and a plurality of positioning blocks 23. The bracket assembly 21 includes a plurality of brackets 210 fixed to one another. The bracket assembly 21 has a first side 211 and a second side 212 that are opposite to each other. The plurality of electronic modules 22 are disposed on the first side 211 of the bracket assembly 21. The plurality of positioning blocks 23 are disposed on the second side 212 of the bracket assembly 21, and each of the plurality of positioning blocks 23 has a support surface 231 disposed on the second side 212. Furthermore, the tiled electronic device may further include a light box 3 mounted on the frame 1. If the electronic module 22 is a non-self-luminous electronic module, the light box 3 may serve as a light source for the tiled electronic device. The light box 3 may be attached to the frame 1 using magnets, screws, or glue.

In the present disclosure, as shown in FIG. 1 and FIG. 2, the number of electronic modules 22 may correspond to the number of brackets 210. Here, the tiled electronic module 2 includes four electronic modules 22 and four brackets 210, and each bracket 210 is provided with at least one positioning block 23 (for example, two positioning blocks 23, but it is not limited thereto) on the side that is not tiled with the adjacent bracket 210 (that is, the first side 214 and the second side 215 of the bracket 210a). Each bracket 210 is not provided with a positioning block 23 on the side that is tiled with the adjacent bracket 210 (that is, the third side 216 and the fourth side 217 of the bracket 210a), but it is not limited thereto, while a plurality of electronic modules 22 may be tiled together according to size requirements, and a corresponding number of brackets 210 and positioning blocks 23 may be provided. In addition, the tiled electronic module 2 of the present disclosure is configured as one electronic module 22 corresponding to one bracket 210, so that the tiling flatness and tiling gap can be controlled.

In the present disclosure, as shown in FIG. 1 and FIG. 2, each of the plurality of brackets 210 may be provided with a first fastening hole 241, and a plurality of electronic modules 22 may be mounted on the plurality of brackets 210 through the first fastening holes 241 of the brackets 210, so as to restrict the relative displacement of the brackets 210 and the electronic modules 22 in the X and Y directions, thereby allowing for quick removal of a specific bracket 210 and electronic module 22 for maintenance. Specifically, the electronic module 22a may be mounted on the bracket 210a through the first fastening hole 241 of the bracket 210a, and the remaining electronic modules 22b, 22c and 22d are fixed to the brackets 210b, 210c and 210d in a similar manner. Here, each bracket 210 is provided with four first fastening holes 241 disposed at the four corners of each bracket 210. However, the present disclosure is not limited thereto, and the number and location of the first fastening holes 241 may be adjusted as needed. Furthermore, in the present disclosure, the electronic modules 22 are fixed to the brackets 210 through the first fastening holes 241 via the first fastening members 251, but it is not limited thereto. The electronic modules 22 may also be attached to the brackets 210 via an adhesive layer.

In the present disclosure, as shown in FIG. 1 and FIG. 2, one of two adjacent brackets 210 may be provided with a second fastening hole 242, and the other of the two adjacent brackets 210 may be provided with a third fastening hole 243. The second fastening hole 242 may be in communication with the third fastening hole 243, and the adjacent brackets 210 are fixed to each other via a second fastening member 252 passing through the second fastening hole 242 and the third fastening hole 243 thereby forming a bracket assembly 21, which restricts relative displacement of the adjacent brackets 210 in the Z direction so as to allow for quick and individual removal of a specific bracket 210 and electronic module 22 for maintenance. Specifically, the bracket 210a and the bracket 210b are fixed to each other via a second fastening member 252 passing through the second fastening hole 242 and the third fastening hole 243, and the remaining brackets 210a, 210b, 210c and 210d in the bracket assembly 21 are fixed in a similar manner. Here, each bracket 210 is provided with eight second fastening holes 242, but it is not limited thereto while, due to viewing angle, only a portion of the second fastening holes 242 is shown. In another embodiment, adjacent brackets 210 may also be fixed to each other through an adhesive layer.

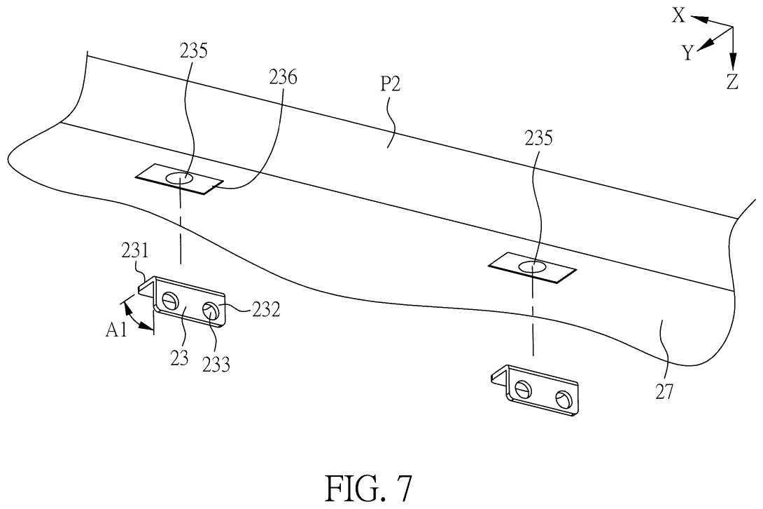

In the present disclosure, as shown in FIG. 1 and FIG. 2, the bracket assembly 21 may include a side surface 213 disposed between the first side 211 and the second side 212. The plurality of positioning blocks 23 may each include a mounting surface 232 connected to the support surface 231. The mounting surface 232 may be fixed to the side surface 213. Furthermore, the side surface 213 of the bracket assembly 21 may be provided with a fourth fastening hole 244. The mounting surface 232 of the positioning block 23 may be provided with a hole 233. The fourth fastening hole 244 may be in communication with the hole 233. Thus, the positioning block 23 is fastened and fixed to the bracket assembly 21 via the third fastening member 253. However, the present disclosure is not limited thereto. The positioning block 23 may also be attached to the bracket assembly 21 via an adhesive layer. Furthermore, an angle A1 may be formed between the mounting surface 232 and the support surface 231 (as shown in FIG. 7). The angle A1 may be substantially equal to 90 degrees.

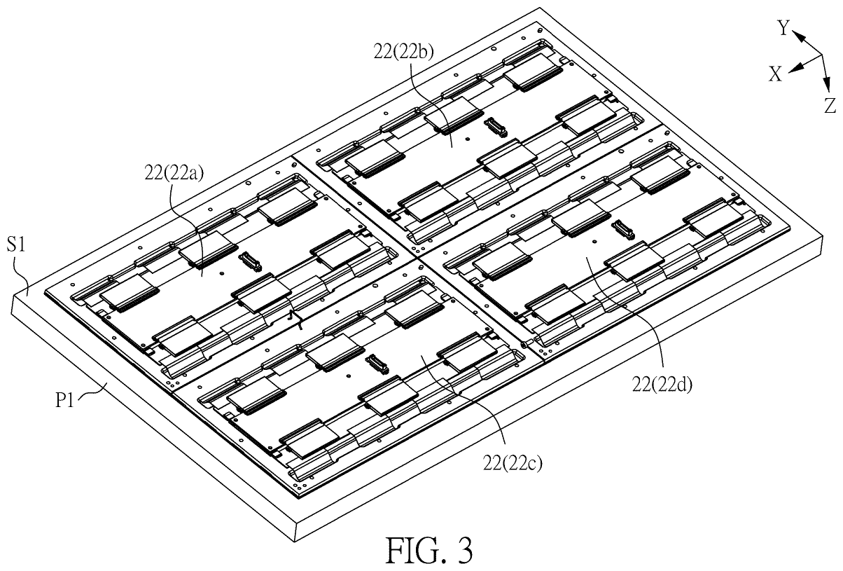

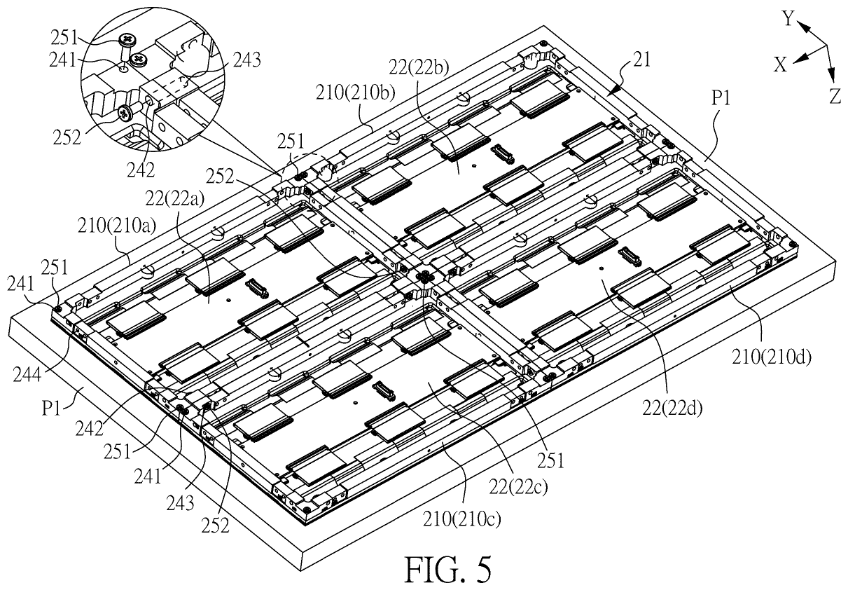

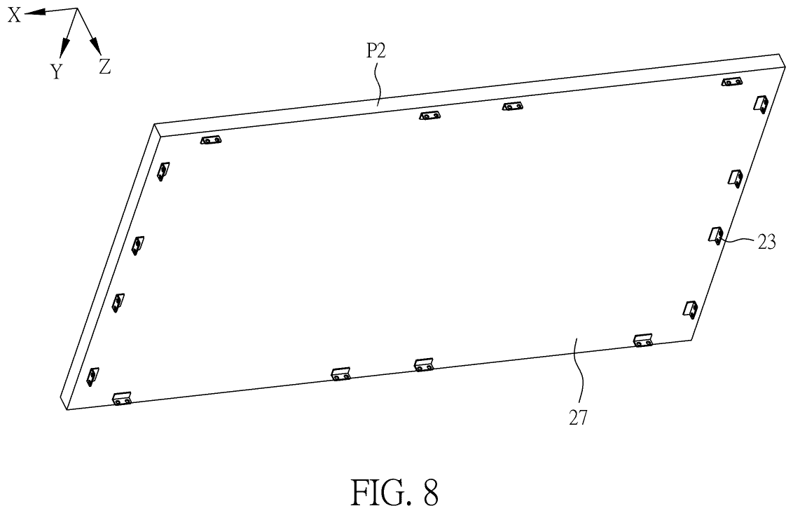

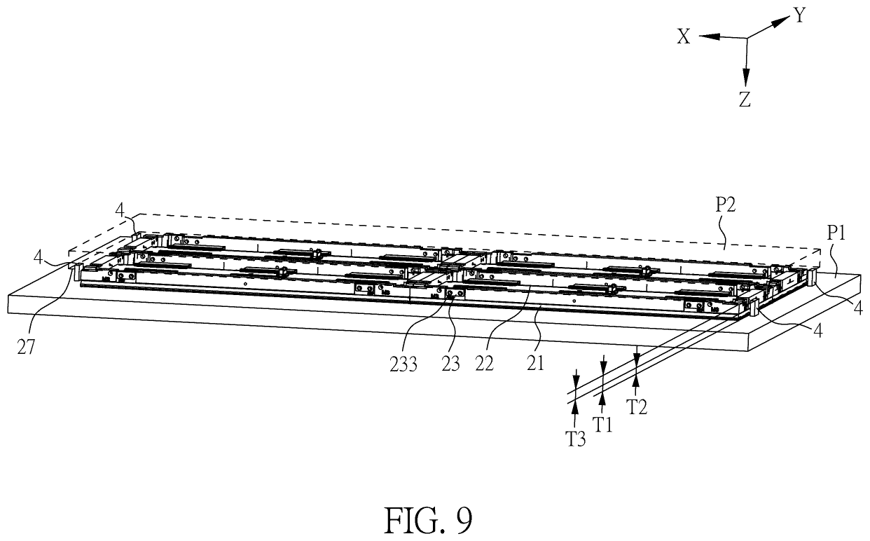

FIG. 3 to FIG. 12 are schematic diagrams illustrating a method for manufacturing a tiled electronic device according to an embodiment of the present disclosure, wherein FIG. 3 and FIG. 5 do not show block gauge 4 in FIG. 9. Next, the method for manufacturing a tiled electronic device according to the present disclosure will be described in detail based on FIG. 3 to FIG. 12, which includes the steps as follows.

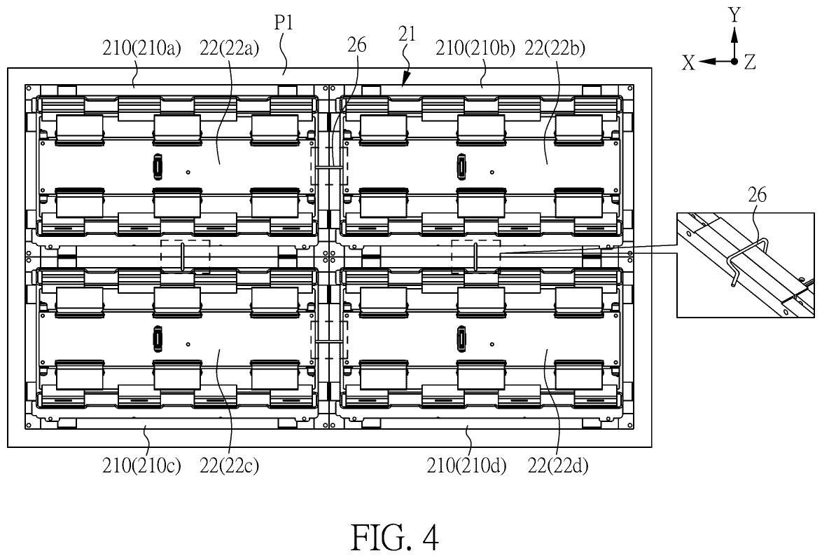

In the present disclosure, as shown in FIG. 3, a first platform P1 is provided, and a plurality of electronic modules 22 are placed side by side on the first platform P1. The display surfaces of the plurality of electronic modules 22 are placed on the first platform P1, with the first platform P1 serving as a reference for the display surfaces of the electronic modules 22, so that the display surfaces of the plurality of electronic modules 22 are maintained flush. Specifically, the display surfaces of four electronic modules 22a, 22b, 22c and 22d are placed side by side on the first platform P1, so that the display surfaces of the electronic modules 22a, 22b, 22c and 22d are flush and the tiling gap is controlled, thereby achieving excellent visual effects. However, the present disclosure is not limited thereto, while a plurality of electronic modules may be tiled together according to size requirements and the plurality of electronic modules 22 may be tiled together using a similar method. Subsequently, as shown in FIG. 4, the plurality of brackets 210 may be fixed by fixing elements 26. Here, the brackets 210a, 210b, 210c and 210d may be temporarily fixed by the fixing elements 26. At this moment, the brackets 210a, 210b, 210c and 210d may move slightly relative to each other. In addition, the fixing element 26 may be, for example, a clamp, but the present disclosure is not limited thereto.

In the present disclosure, as shown in FIG. 5, a plurality of brackets 210 are respectively fixed to a plurality of electronic modules 22, and the plurality of brackets 210 are fixed to form a bracket assembly 21. Here, the plurality of brackets 210 may be respectively fixed to the plurality of electronic modules 22 using the first fastening members 251, and two adjacent brackets 210 may be fixed to each other using the second fastening member 252 to form the bracket assembly 21. Specifically, the bracket 210a may be fixed to the electronic module 22a via the first fastening member 251 through the first fastening hole 241, thereby limiting relative displacement between the bracket 210a and the electronic module 22a in the X and Y directions. Furthermore, the bracket 210a and the bracket 210b may be fixed to each other via the second fastening member 252 through the second fastening hole 242 and the third fastening hole 243, thereby limiting relative displacement between the brackets 210a and 210b in the Z direction. Thus, it is able to achieve the control of the tiling flatness and tiling gap, while the remaining electronic modules 22b, 22c and 22d are fixed to the brackets 210b, 210c and 210d in a similar manner, and the brackets 210a, 210b, 210c and 210d are fixed to each other in a similar manner. Since there are slight tolerances between each bracket 210 and each electronic module 22, and slight errors will be generated during the fastening and fixing process, after the tiling flatness and tiling gap adjustments are completed, it is necessary to use an adjustment mechanism to correct the thickness of the tiled electronic module 2, which may reduce the precision requirements for component manufacturing thereby reducing costs.

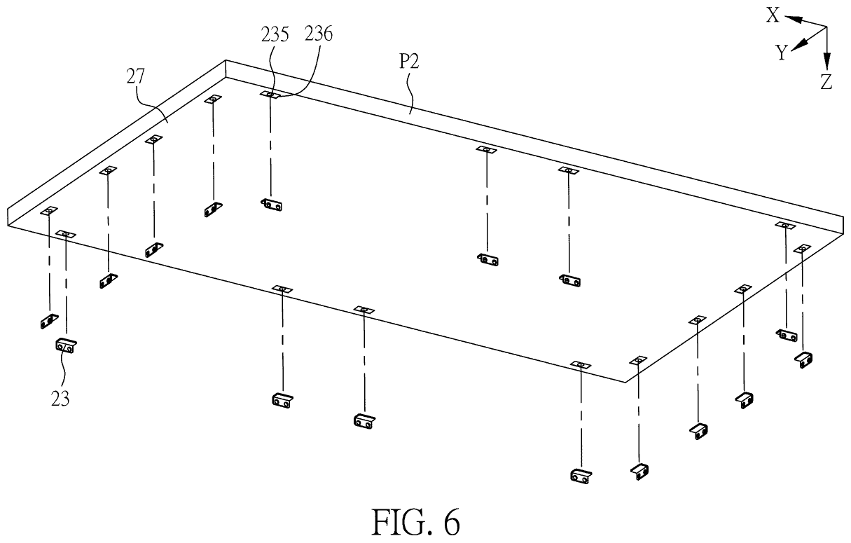

In the present disclosure, as shown in FIG. 6 to FIG. 8, a second platform P2 is provided, and a plurality of positioning blocks 23 are disposed on one side 27 of the second platform P2. The positioning blocks 23 may be attracted to the side 27 of the second platform P2 by magnetic elements 235. Furthermore, a plurality of recesses 236 may be disposed on the side 27 of the second platform P2. The recesses 236 may correspond to the support surfaces 231 of the positioning blocks 23, respectively, so as to facilitate alignment between the second platform P2 and the positioning blocks 23.

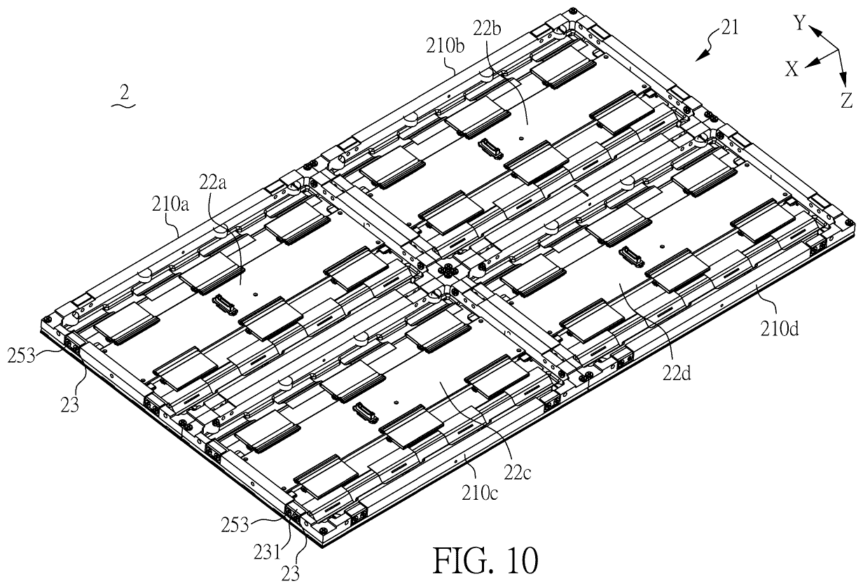

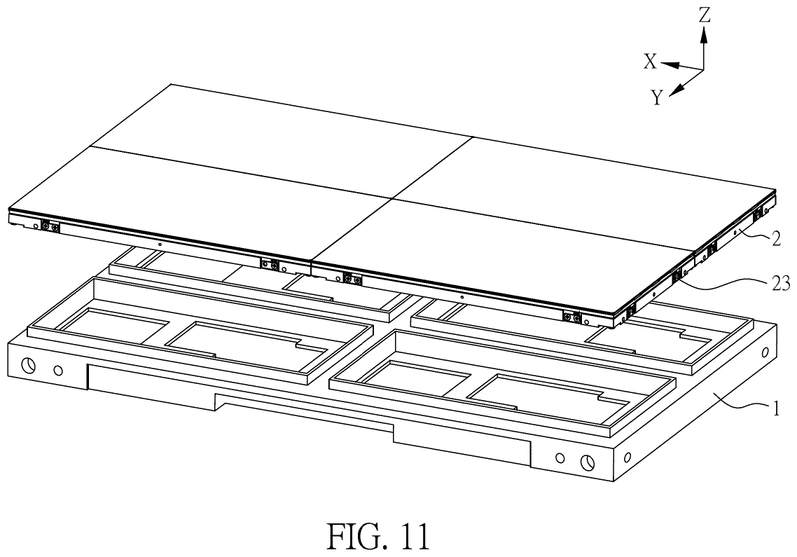

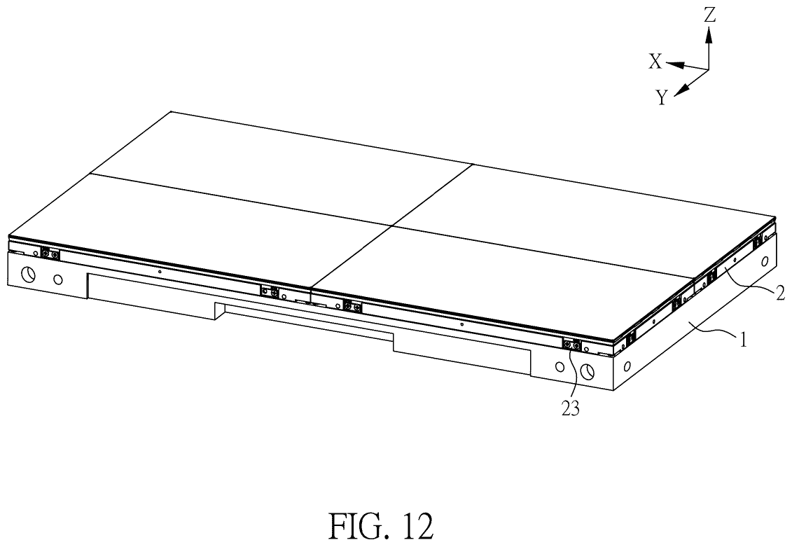

In the present disclosure, as shown in FIG. 9, the first platform P1 may be provided with a block gauge 4, but it is not limited thereto, and another platform provided with a block gauge may also be provided. Here, the first platform P1 may be provided with four block gauges 4, which are adjacent to and disposed on the outside of the bracket assembly 21 and the electronic module 22, so that the first platform P1 and the side 27 of the second platform P2 are separated by a predetermined distance T1, wherein the predetermined distance T1 is the height of the block gauge 4, the second platform P2 is used as a plane, and the hole 233 of the positioning block 23 is fastened and fixed to the fourth fastening hole 244 of the bracket assembly 21 (as shown in FIG. 5) so as to calibrate the thickness of the tiled electronic module 2. Next, as shown in FIG. 10, a plurality of positioning blocks 23 are fixed to the bracket assembly 21. Here, the plurality of positioning blocks 23 may be fixed to the bracket assembly 21 respectively through the third fastening member 253, and the second platform P2 (as shown in FIG. 9) is removed, thereby completing the calibration of the thickness of the tiled electronic module 2. In addition, as shown in FIG. 11 to FIG. 12, the tiled electronic module 2 is flipped over and the supporting surfaces 231 of the plurality of positioning blocks 23 (as shown in FIG. 10) are placed against the frame 1 to obtain a tiled electronic device, wherein the tiled electronic module 2 and the frame 1 may be fixed by magnet attraction, screw fastening or gluing.

In the present disclosure, as shown in FIG. 9, the predetermined distance T1 may be between 50 μm and 1 mm, for example, between 50 μm and 900 μm, between 50 μm and 800 μm, between 50 μm and 500 μm, between 50 μm and 250 μm, between 50 μm and 100 μm, or approximately 50 μm, but the present disclosure is not limited thereto. The predetermined distance T1 is greater than the thickness T2 of the electronic module 22, and the predetermined distance T1 may be adjusted according to the thickness T2 of the electronic module 22. The predetermined distance T1 minus the thickness T2 of the plurality of electronic modules 22 may be the minimum distance T3, and the minimum distance T3 may be smaller than or equal to 10 μm, for example, smaller than or equal to 8 μm, smaller than or equal to 7 μm, smaller than or equal to 5 μm, or approximately 10 μm, 8 μm, 7 μm, or 5 μm.

In the present disclosure, as shown in FIG. 9, the materials of the first platform P1 and the second platform P2 may be the same or different. The materials of the first platform P1 and the second platform P2 may each include glass, quartz, sapphire, ceramic, plastic, polycarbonate (PC), polyimide (PI), polypropylene (PP), polyethylene terephthalate (PET), polymethylmethacrylate (PMMA), other suitable materials, or a combination thereof, but the present disclosure is not limited thereto.

In the present disclosure, the material of the adhesive layer may include, for example, polyvinyl butyral (PVB), ethylene vinyl acetate (EVA), optical clear adhesive (OCA), optical clear resin (OCR), other suitable materials, or a combination thereof, but the present disclosure is not limited thereto.

In summary, the tiled electronic device and the method for manufacturing the tiled electronic device of the present disclosure may control the tiling flatness and tiling gap to achieve excellent visual effects, may correct the tolerances of each component in the tiled electronic module and the errors in the fixing process, or may reduce the precision requirements for component manufacturing, thereby reducing costs.

The aforementioned specific embodiments should be interpreted as merely illustrative, and not limiting the rest of the present disclosure in any way.

1. A tiled electronic device, comprising:
a frame; and
a tiled electronic module, including:
a bracket assembly including a plurality of brackets fixed to one another, the bracket assembly being provided with a first side and a second side opposite to each other;
a plurality of electronic modules disposed on the first side of the bracket assembly; and
a plurality of positioning blocks disposed on the bracket assembly, each of the plurality of positioning blocks having a support surface disposed on the second side,
wherein the tiled electronic module is placed against the frame through the support surfaces.

2. The tiled electronic device as claimed in claim 1, wherein each of the plurality of brackets is provided with a first fastening hole, and the plurality of electronic modules are mounted on the plurality of brackets through the first fastening holes of the plurality of brackets.

3. The tiled electronic device as claimed in claim 1, wherein one of two adjacent ones of the plurality of brackets is provided with a second fastening hole, the other of the two adjacent ones of the plurality of brackets is provided with a third fastening hole, and the second fastening hole is connected to the third fastening hole.

4. The tiled electronic device as claimed in claim 1, wherein the bracket assembly has a side surface disposed between the first side and the second side, each of the plurality of positioning blocks has a mounting surface connected to the support surface, and the mounting surface is fixed to the side surface.

5. The tiled electronic device as claimed in claim 4, wherein the side surface is provided with a fourth fastening hole, the mounting surface is provided with a hole, and the fourth fastening hole is in communication with the hole.

6. The tiled electronic device as claimed in claim 4, wherein an angle is formed between the mounting surface and the support surface, and the angle is substantially equal to 90 degrees.

7. The spliced electronic device as claimed in claim 1, further comprising a light box mounted on the frame.

8. The tiled electronic device as claimed in claim 2, wherein the plurality of electronic modules are respectively fastened and fixed to the plurality of brackets by a plurality of first fastening members passing through the first fastening holes.

9. The tiled electronic device as claimed in claim 3, wherein the adjacent brackets are fixed to each other through a second fastening member passing through the second fastening hole and the third fastening hole.

10. A method for manufacturing a tiled electronic device, comprising the steps of:
providing a first platform;
placing a plurality of electronic modules in parallel on the first platform;
fixing a plurality of brackets on the plurality of electronic modules, respectively;
fixing the plurality of brackets to form a bracket assembly;
providing a second platform and arranging a plurality of positioning blocks on one side of the second platform;
enabling the first platform and the side of the second platform to be separated by a predetermined distance;
fixing the plurality of positioning blocks on the bracket assembly; and
placing the plurality of positioning blocks against a frame.

11. The method as claimed in claim 10, wherein the plurality of positioning blocks are attracted onto the side of the second platform by a magnetic element.

12. The method as claimed in claim 10, wherein the predetermined distance is between 50 μm and 1 mm.

13. The method as claimed in claim 10, wherein the predetermined distance minus a thickness of the plurality of electronic modules is a minimum distance, and the minimum distance is smaller than or equal to 10 μm.

14. The method as claimed in claim 10, wherein a display surface of the plurality of electronic modules is placed on the first platform.

15. The method as claimed in claim 10, further comprising, before the plurality of brackets are respectively fixed to the plurality of electronic modules, the step of fixing the plurality of brackets with fixing elements.

16. The method as claimed in claim 10, wherein the plurality of brackets are respectively fixed to the plurality of electronic modules through first fastening members.

17. The method as claimed in claim 10, wherein two adjacent ones of the plurality of brackets are fixed to each other via a second fastening member to form the bracket assembly.

18. The method as claimed in claim 10, wherein the plurality of positioning blocks are respectively fixed to the bracket assembly via third fastening members.

19. The method as claimed in claim 10, wherein a plurality of recesses are provided on the side of the second platform, and the plurality of recesses respectively correspond to support surfaces of the plurality of positioning blocks.

20. The method as claimed in claim 10, wherein the first platform is provided with a plurality of block gauges adjacent to and disposed outside the bracket assembly and the electronic modules, and a height of the block gauge is the predetermined distance.
